(19) United States
(12) Patent Application Publication
(10) Pub. No.: US 2025/0174546 A1
(43) Pub. Date: May 29, 2025

(54) SEMICONDUCTOR DEVICE, AND PRODUCTION METHOD FOR SEMICONDUCTOR DEVICE

(71) Applicant: SUMITOMO ELECTRIC DEVICE INNOVATIONS, INC., Kanagawa (JP)

(72) Inventor: Yukinori NOSE, Kanagawa (JP)

(21) Appl. No.: 18/941,474

(22) Filed: Nov. 8, 2024

(30) Foreign Application Priority Data
Nov. 29, 2023 (JP) 2023-202075

(51) Int. Cl. H01L 23/498; H01L 21/311; H01L 21/768; H01L 27/06

(52) U.S. Cl. CPC H01L 23/49883; H01L 21/31116; H01L 21/76805; H10D 84/811

(57) ABSTRACT

A semiconductor device includes a substrate including a first main surface and a second main surface that is opposite to the first main surface; an organic stopper layer that is provided over the first main surface; a first electrode that is provided over the organic stopper layer; an insulating film that is provided on the first electrode; a second electrode that is provided on the insulating film; a first through-hole that penetrates through the substrate and the organic stopper layer and reaches the first electrode; and a metal layer that covers the second main surface and a first inner wall surface of the first through-hole and is electrically connected to the first electrode.

### CROSS-REFERENCE TO RELATED APPLICATIONS

This application is based on and claims priority to Japanese Patent Application No. 2023-202075, filed on Nov. 29, 2023, the entire contents of which are incorporated herein by reference.

### TECHNICAL FIELD

The present disclosure relates to a semiconductor device, and a production method for the semiconductor device.

### BACKGROUND

For example, a metal insulator metal (MIM)-type capacitor, in which a lower electrode, an insulating film, and an upper electrode are stacked, may be formed in a semiconductor integrated circuit, such as a monolithic microwave integrated circuit (MMIC). See Unexamined Japanese Patent Application Publication Nos. 2004-006958, 2018-037497, and 2020-017647.

### SUMMARY

A semiconductor device of the present disclosure includes: a substrate including a first main surface and a second main surface that is opposite to the first main surface; an organic stopper layer that is provided over the first main surface; a first electrode that is provided over the organic stopper layer; an insulating film that is provided on the first electrode; a second electrode that is provided on the insulating film; a first through-hole that penetrates through the substrate and the organic stopper layer and reaches the first electrode; and a metal layer that covers the second main surface and a first inner wall surface of the first through-hole and is electrically connected to the first electrode.

### BRIEF DESCRIPTION OF THE DRAWINGS

FIG. 1 is a cross-sectional view illustrating a semiconductor device according to an embodiment of the present disclosure;

FIG. 2 is a cross-sectional view illustrating a production method for the semiconductor device according to the embodiment (part 1);

FIG. 3 is a cross-sectional view illustrating the production method for the semiconductor device according to the embodiment (part 2);

FIG. 4 is a cross-sectional view illustrating the production method for the semiconductor device according to the embodiment (part 3);

FIG. 5 is a cross-sectional view illustrating the production method for the semiconductor device according to the embodiment (part 4);

FIG. 6 is a cross-sectional view illustrating the production method for the semiconductor device according to the embodiment (part 5);

FIG. 7 is a cross-sectional view illustrating the production method for the semiconductor device according to the embodiment (part 6);

FIG. 8 is a cross-sectional view illustrating the production method for the semiconductor device according to the embodiment (part 7);

FIG. 9 is a cross-sectional view illustrating the production method for the semiconductor device according to the embodiment (part 8); and

FIG. 10 is a cross-sectional view illustrating the production method for the semiconductor device according to the embodiment (part 9).

### DETAILED DESCRIPTION

In order to reduce the size of a semiconductor device, it is conceivable to form a through-hole that penetrates through a substrate and reaches a lower electrode, and to provide the back surface of the substrate with a metal layer connected to the lower electrode through the through-hole. However, at the time of forming the through-hole, the lower electrode may be damaged, and an insulating film between the lower electrode and the upper electrode may be damaged. The damage to the lower electrode and the damage to the insulating film lead to a reduction in the breakdown voltage of the capacitor. The damage to the lower electrode and the like can be suppressed by providing a thick film between the substrate and the lower electrode. However, in this case, such a thick film requires a long etching time, resulting in reduction in the throughput.

It is an object of the present disclosure to provide: a semiconductor device that can be reduced in terms of the size thereof and suppressed in terms of a reduction in the breakdown voltage of a capacitor; and a production method for the semiconductor device.

According to the present disclosure, it is possible to reduce the size of the semiconductor device and suppress the reduction in the breakdown voltage of the capacitor.

### DESCRIPTION OF EMBODIMENTS OF THE PRESENT DISCLOSURE

First, embodiments of the present disclosure will be described.

[1] A semiconductor device according to an

aspect of the present disclosure includes: a substrate including a first main surface and a second main surface that is opposite to the first main surface; an organic stopper layer that is provided over the first main surface; a first electrode that is provided over the organic stopper layer; an insulating film that is provided on the first electrode; a second electrode that is provided on the insulating film; a first through-hole that penetrates through the substrate and the organic stopper layer and reaches the first electrode; and a metal layer that covers the second main surface and a first inner wall surface of the first through-hole and is electrically connected to the first electrode.

The organic stopper layer is provided between the substrate and the first electrode, and the organic stopper layer functions as an etching stopper at the time of forming the first through-hole in the substrate. This can suppress damage to the first electrode and the insulating film at the time of forming the first through-hole in the substrate. Therefore, the size of the semiconductor device can be reduced while suppressing a reduction in the breakdown voltage of a MIM-type capacitor that includes the first electrode, the insulating film, and the second electrode.

[2] In [1], the semiconductor device may further include: a semiconductor layer that is provided on the first main surface; a third electrode that is provided on the semiconductor layer; and a second through-hole that penetrates through the substrate and the semiconductor layer and reaches the third electrode, in which the organic stopper layer may be provided over the semiconductor layer, the first through-hole may penetrate through the semiconductor layer, and the metal layer may cover a second inner wall surface of the second through-hole and be electrically connected to the third electrode. In this case, it is possible to form a MMIC including: a semiconductor element, such as a transistor, including the semiconductor layer and the third electrode; and a MIM-type capacitor.

[3] In [1] or [2], the organic stopper layer may include polyimide or benzocyclobutene. In this case, the organic stopper layer is readily formed to have a desired thickness.

[4] In any one of [1] to [3], a thickness of the organic stopper layer may be 1 micrometer (μm) or more and 10 micrometers (μm) or less. In this case, the organic stopper layer is readily allowed to function as an etching stopper during processing of a substrate or the like while reducing the time required for etching of the organic stopper layer.

[5] In any one of [1] to [4], the semiconductor device may further include an inorganic stopper layer that is provided between the organic stopper layer and the first electrode, and the first through-hole may penetrate through the inorganic stopper layer. In this case, the inorganic stopper layer provides favorable adhesiveness between the organic stopper layer and the first electrode. Also, the inorganic stopper layer functions as an etching stopper when the first through-hole penetrates through the organic stopper layer.

[6] In [5], a thickness of the inorganic stopper layer may be 20 nanometers (nm) or more and 500 nanometers (nm) or less. In this case, the inorganic stopper layer is readily allowed to function as an etching stopper during processing of the organic stopper layer while reducing the time required for etching of the inorganic stopper layer.

[7] A production method for a semiconductor device according to another embodiment of the present disclosure includes: providing a structure that includes a substrate including a first main surface and a second main surface that is opposite to the first main surface, an organic stopper layer that is provided over the first main surface, a first electrode that is provided over the organic stopper layer, an insulating film that is provided on the first electrode, and a second electrode that is provided on the insulating film; performing first reactive ion etching to form a first through-hole that overlaps with the first electrode in a plan view perpendicular to the first main surface, penetrates the substrate, and reaches the organic stopper layer; performing second reactive ion etching to extend the first through-hole so as to penetrate through the organic stopper layer and reach the first electrode; and forming a metal layer that covers the second main surface and a first inner wall surface of the first through-hole and is electrically connected to the first electrode.

During the first reactive ion etching, the organic stopper layer functions as an etching stopper. This can suppress damage to the first electrode and the insulating film due to the first reactive ion etching. Also, the second reactive ion etching for extending the first through-hole can be performed under conditions in which damage is not likely to occur to the first electrode and the insulating film. Therefore, the size of the semiconductor device can be reduced while suppressing a reduction in the breakdown voltage of the MIM-type capacitor including the first electrode, the insulating film, and the second electrode.

[8] In [7], the structure may further include a semiconductor layer provided on the first main surface and a third electrode provided on the semiconductor layer, the organic stopper layer may be provided over the semiconductor layer, performing the first reactive ion etching may include: performing third reactive ion etching to form a portion of the first through-hole, the portion penetrating through the substrate and reaching the semiconductor layer, and to form a second through-hole that overlaps with the third electrode in the plan view, penetrates through the substrate, and reaches the semiconductor layer; and performing fourth reactive ion etching to extend the first through-hole so as to penetrate through the semiconductor layer and reach the organic stopper layer, and to extend the second through- hole so as to penetrate through the semiconductor layer and reach the third electrode, and the metal layer may cover a second inner wall surface of the second through-hole and be electrically connected to the third electrode. In this case, it is possible to form a MMIC including: a semiconductor element, such as a transistor, including the semiconductor layer and the third electrode; and a MIM-type capacitor.

[9] In [7] or [8], the structure may further include an inorganic stopper layer that is provided between the organic stopper layer and the first electrode, performing the second reactive ion etching may include performing fifth reactive ion etching to extend the first through-hole so as to penetrate through the organic stopper layer and reach the inorganic stopper layer, and performing sixth reactive ion etching to extend the first through-hole so as to penetrate through the inorganic stopper layer and reach the first electrode. In this case, the inorganic stopper layer provides favorable adhesiveness between the organic stopper layer and the first electrode. Also, the inorganic stopper layer functions as an etching stopper when the first through-hole penetrates through the organic stopper layer. The inorganic stopper layer may be thin. Thus, the sixth reactive ion etching can be performed under conditions in which damage is not likely to occur to the first electrode and the insulating film.

[10] In [9], a reactive gas containing oxygen may be used in the fifth reactive ion etching. In this case, the organic stopper layer can be readily etched.

### DETAILS OF EMBODIMENTS OF PRESENT DISCLOSURE

Embodiments of the present disclosure will be described below in detail, but the present disclosure is not limited thereto. In the present specification and drawings, components having substantially the same functional configuration are denoted by the same reference symbols, and duplicate description thereof may be omitted. In the following description, an XYZ orthogonal coordinate system is used. However, this coordinate system is provided for the description, and does not limit the orientation of the semiconductor device. Also, when viewed from a given point, the +Z side may be referred to as upward, upper side, or above, and the −Z side may be referred to as downward, lower side, or below.

### Configuration of Semiconductor Device

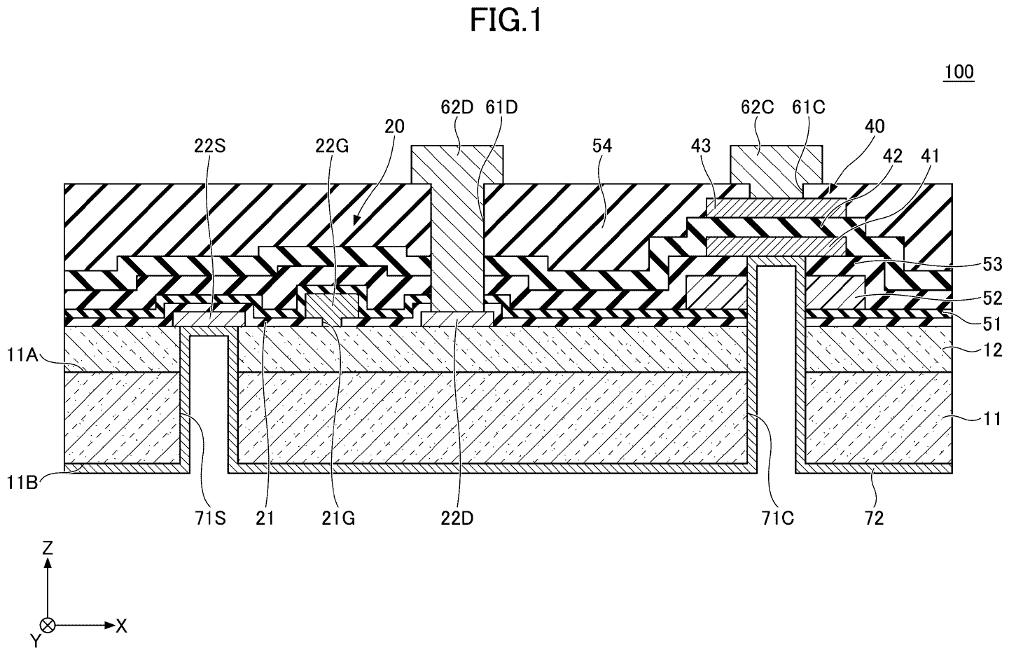

Embodiments relate to a semiconductor device including: a field effect transistor (FET), such as a GaN-based high electron mobility transistor (HEMT) or the like; and a MIM-type capacitor. FIG. 1 is a cross-sectional view illustrating a semiconductor device according to an embodiment of the present disclosure.

As illustrated in FIG. 1, a semiconductor device 100 according to the embodiment includes a substrate 11, a semiconductor layer 12, a gate electrode 22G, a source electrode 22S, a drain electrode 22D, a lower electrode 41, an insulating film 42, an upper electrode 43, and a back electrode 72.

The substrate 11 is, for example, a silicon carbide (SiC) substrate. The substrate 11 includes a first main surface 11A and a second main surface 11B opposite to the first main surface 11A. The first main surface 11A is located upward (+Z side) of the second main surface 11B.

The semiconductor layer 12 is provided on the first main surface 11A. The semiconductor layer 12 is, for example, a nitride semiconductor layer containing gallium (Ga). The nitride semiconductor layer includes an electron transport layer (channel layer), an electron supply layer (barrier layer), and the like that form a HEMT.

The source electrode 22S and the drain electrode 22D are provided on the semiconductor layer 12. The source electrode 22S and the drain electrode 22D are in an ohmic contact with the semiconductor layer 12. The semiconductor layer 12 may include a plurality of regrown layers, and the source electrode 22S and the drain electrode 22D may be provided on the regrown layers. The source electrode 22S is an example of the third electrode.

The semiconductor device 100 includes an insulating film 21. The insulating film 21 is provided on the source electrode 22S, the drain electrode 22D, and the semiconductor layer 12, and covers the source electrode 22S, the drain electrode 22D, and the semiconductor layer 12. The insulating film 21 may be opened on the source electrode 22S and the drain electrode 22D. The insulating film 21 includes, for example, a silicon nitride (SiN) film, a silicon oxide

(SiO₂) film, an aluminum oxide (Al₂O₃) film, a hafnium oxide (HfO₂) film, or a zirconium oxide (ZrO₂) film. The insulating film 21 may include a stack of two or more of the above films.

A gate opening 21G is formed in the insulating film 21. The opening 21G is located between the source electrode 22S and the drain electrode 22D in a plan view perpendicular to the first main surface 11A. Hereinafter, the term “plan view” means the “plan view perpendicular to the first main surface 11A”. The gate electrode 22G is provided on the insulating film 21 between the source electrode 22S and the drain electrode 22D in the plan view, and is in a Schottky contact with the semiconductor layer 12 through the opening 21G.

The semiconductor device 100 includes a FET 20 including the semiconductor layer 12, the gate electrode 22G, the source electrode 22S, and the drain electrode 22D. The FET 20 is, for example, a HEMT.

The semiconductor device 100 further includes an insulating film 51, an organic stopper layer 52, an inorganic stopper layer 53, and an interlayer insulating film 54.

The insulating film 51 is provided on the gate electrode 22G and the insulating film 21, and covers the gate electrode 22G and the insulating film 21. The insulating film 51 includes, for example, a silicon nitride (SiN) film, a silicon oxide (SiO₂) film, an aluminum oxide (Al₂O₃) film, a hafnium oxide (HfO₂) film, or a zirconium oxide (ZrO₂) film. The insulating film 51 may include a stack of two or more of the above films. The insulating films 21 and 51 provide favorable adhesiveness between the semiconductor layer 12 and the organic stopper layer 52.

The organic stopper layer 52 is provided on the insulating film 51 apart from the FET 20. In other words, the organic stopper layer 52 is provided over the first main surface 11A. The organic stopper layer 52 includes, for example, polyimide or benzocyclobutene (BCB). The thickness of the organic stopper layer 52 is, for example, 1 μm or more and 10 μm or less. The thickness of the organic stopper layer 52 can be measured through observation using a scanning electron microscope (SEM).

The inorganic stopper layer 53 is provided on the organic stopper layer 52 and the insulating film 51, and covers the organic stopper layer 52 and the insulating film 51. The inorganic stopper layer 53 includes, for example, a silicon nitride (SiN) film, a silicon oxide (SiO₂) film, an aluminum oxide (Al₂O₃) film, a hafnium oxide (HfO₂) film, or a zirconium oxide (ZrO₂) film. The inorganic stopper layer 53 may include a stack of two or more of the above films. The thickness of the inorganic stopper layer 53 is, for example, 20 nm or more and 500 nm or less. The thickness of the inorganic stopper layer 53 can be measured through observation using a SEM.

The lower electrode 41 is provided over the organic stopper layer 52 and on the inorganic stopper layer 53. In other words, the inorganic stopper layer 53 is provided between the organic stopper layer 52 and the lower electrode 41. For example, in the plan view, the outline of the lower electrode 41 is inward of the outline of the organic stopper layer 52. The lower electrode 41 includes, for example, a titanium (Ti) film and a gold (Au) film thereon. The lower electrode 41 is an example of the first electrode.

The insulating film 42 is provided on the lower electrode 41 and the inorganic stopper layer 53, and covers the lower electrode 41 and the inorganic stopper layer 53. The insulating film 42 includes, for example, a silicon nitride (SiN) film, a silicon oxide (SiO₂) film, an aluminum oxide (Al₂O₃) film, a hafnium oxide (HfO₂) film, or a zirconium oxide (ZrO₂) film. The insulating film 42 may include a stack of two or more of the above films.

The upper electrode 43 is provided over the organic stopper layer 52 and on the insulating film 42. In other words, the insulating film 42 is provided between the lower electrode 41 and the upper electrode 43. For example, in the plan view, the outline of the upper electrode 43 is inward of the outline of the organic stopper layer 52. The upper electrode 43 includes, for example, a titanium (Ti) film and a gold (Au) film thereon. The upper electrode 43 is an example of the second electrode.

The semiconductor device 100 includes a MIM-type capacitor 40 including the lower electrode 41, the insulating film 42, and the upper electrode 43.

The interlayer insulating film 54 is provided on the upper electrode 43 and the insulating film 42, and covers the upper electrode 43 and the insulating film 42. For example, the upper surface of the interlayer insulating film 54 may be flattened. An opening 61C penetrating through the interlayer insulating film 54 is formed in the interlayer insulating film 54. The opening 61C reaches the upper electrode 43. An opening 61D penetrating through the interlayer insulating film 54, the insulating film 42, the inorganic stopper layer 53, the insulating film 51, and the insulating film 21 is formed in the interlayer insulating film 54, the insulating film 42, the inorganic stopper layer 53, the insulating film 51, and the insulating film 21. The opening 61D reaches the drain electrode 22D. A different opening may be formed in the same manner as in the opening 61D, and this different opening may reach the source electrode 22S.

The semiconductor device 100 has interconnects 62C and 62D. The interconnect 62C is provided on the interlayer insulating film 54, and contacts the upper electrode 43 through the opening 61C. The interconnect 62D is provided on the interlayer insulating film 54, and contacts the drain electrode 22D through the opening 61D.

A through-hole 71S penetrating through the substrate 11 and the semiconductor layer 12 is formed in the substrate 11 and the semiconductor layer 12. The through-hole 71S reaches the source electrode 22S. A through-hole 71C penetrating through the substrate 11, the semiconductor layer 12, the insulating film 21, the insulating film 51, the organic stopper layer 52, and the inorganic stopper layer 53 is formed in the substrate 11, the semiconductor layer 12, the insulating film 21, the insulating film 51, the organic stopper layer 52, and the inorganic stopper layer 53. The through-hole 71C reaches the lower electrode 41. The through-hole 71C is an example of the first through-hole, and the through-hole 71S is an example of the second through-hole.

The back electrode 72 is formed on the second main surface 11B of the substrate 11, the inner wall surface of the through-hole 71C, the lower surface of the lower electrode 41, the inner wall surface of the through-hole 71S, and the lower surface of the source electrode 22S. The back electrode 72 contacts the lower electrode 41 and the source electrode 225, and covers the second main surface 11B, the inner wall surface of the through-hole 71C, and the inner wall surface of the through-hole 71S. For example, the back electrode 72 is formed of a gold (Au) layer. The back electrode 72 includes, for example, a seed layer and a plating layer. For example, the back electrode 72 is grounded, and a ground potential is applied to the lower electrode 41 and the source electrode 22S. The back electrode 72 is an example of the metal layer.

### Production Method for Semiconductor Device

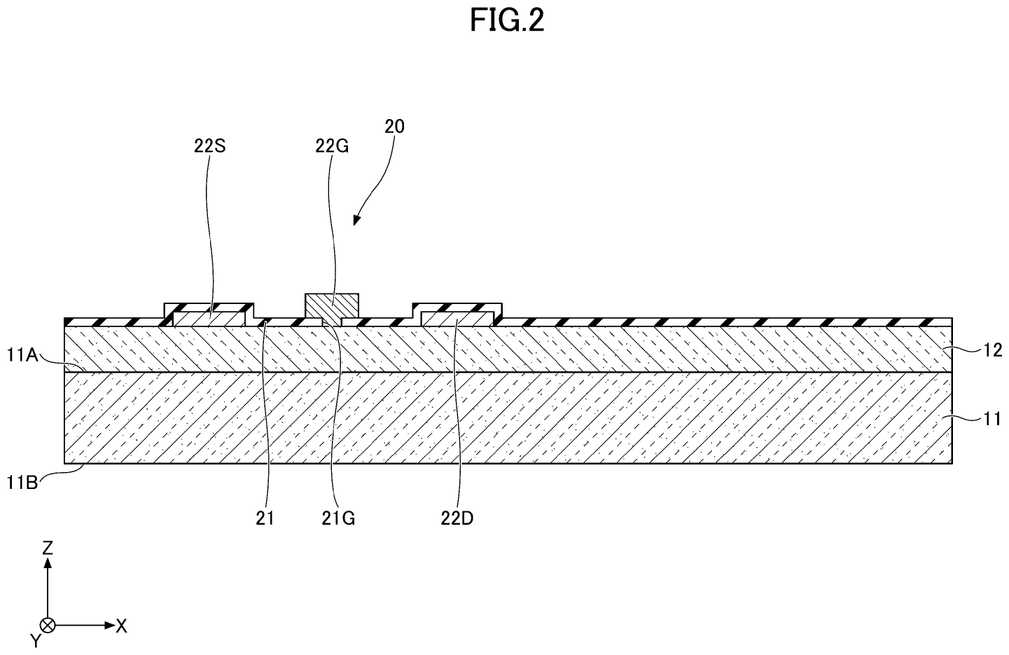

Next, a production method for the semiconductor device 100 according to the embodiment will be described. FIGS. 2 to 10 are cross-sectional views illustrating the production method for the semiconductor device 100 according to the embodiment.

First, as illustrated in FIG. 2, a semiconductor layer 12 is formed on a substrate 11, for example, through metal organic chemical vapor deposition (MOCVD). The substrate 11 includes the first main surface 11A and the second main surface 11B opposite to the first main surface 11A.

Next, the source electrode 22S and the drain electrode 22D are formed on the semiconductor layer 12. For the formation of the source electrode 22S and the drain electrode 22D, a metal film is grown through vapor deposition using a mask for growth, and then the mask for growth is removed. That is, the source electrode 22S and the drain electrode 22D can be formed, for example, through vapor deposition and lift-off. Next, the insulating film 21 is formed on the source electrode 22S, the drain electrode 22D, and the semiconductor layer 12. The insulating film 21 can be formed, for example, through plasma CVD or sputtering. The insulating film 21 covers the source electrode 22S, the drain electrode 22D, and the semiconductor layer 12.

Next, the opening 21G is formed in the insulating film 21. For the formation of the opening 21G, for example, reactive ion etching (RIE) using a resist pattern as a mask is performed. For the etching of the insulating film 21, a reactive gas containing fluorine (F) or chlorine (Cl) is used. Next, the gate electrode 22G is formed on the insulating film 21. For the formation of the gate electrode 22G, a metal film is grown through vapor deposition using a mask for growth, and then the mask for growth is removed. That is, the gate electrode 22G can be formed, for example, through vapor deposition and lift-off. The gate electrode 22G is in a Schottky contact with the semiconductor layer 12 through the opening 21G.

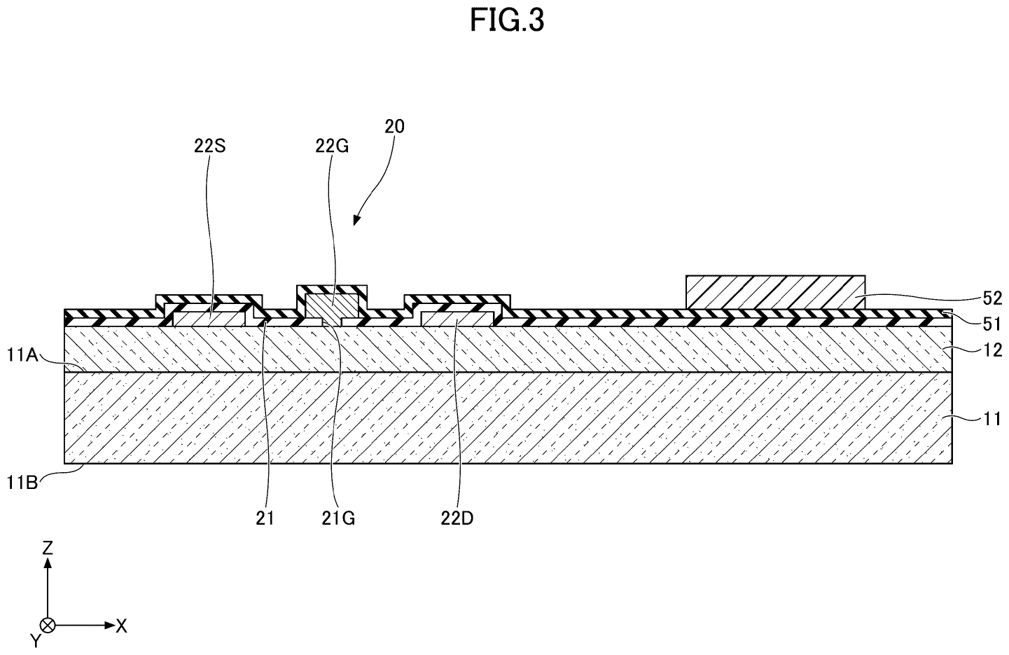

Next, as illustrated in FIG. 3, the insulating film 51 is formed on the gate electrode 22G and the insulating film 21. The insulating film 51 can be formed, for example, through plasma CVD or sputtering. The insulating film 51 covers the gate electrode 22G and the insulating film 21. Next, the organic stopper layer 52 is formed on the insulating film 51. In other words, the organic stopper layer 52 is formed over the first main surface 11A. The organic stopper layer 52 is formed on the insulating film 51 apart from the FET 20. The organic stopper layer 52 includes, for example, polyimide or benzocyclobutene. The organic stopper layer 52 can be formed, for example, through spin coating, light exposure, development, and baking of a photosensitive polyimide or a photosensitive benzocyclobutene. The organic stopper layer 52 may be formed through spin coating, baking, and etching of a non-photosensitive polyimide or a non-photosensitive benzocyclobutene.

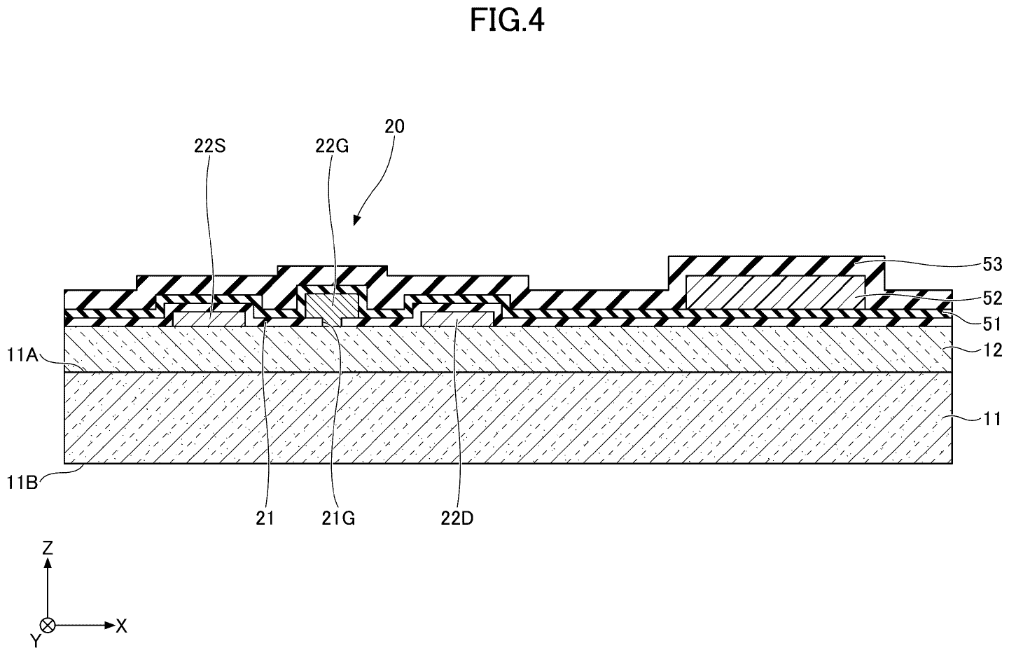

Next, as illustrated in FIG. 4, the inorganic stopper layer 53 is formed on the organic stopper layer 52 and the insulating film 51. The inorganic stopper layer 53 can be formed, for example, through plasma CVD or sputtering. The inorganic stopper layer 53 covers the organic stopper layer 52 and the insulating film 51.

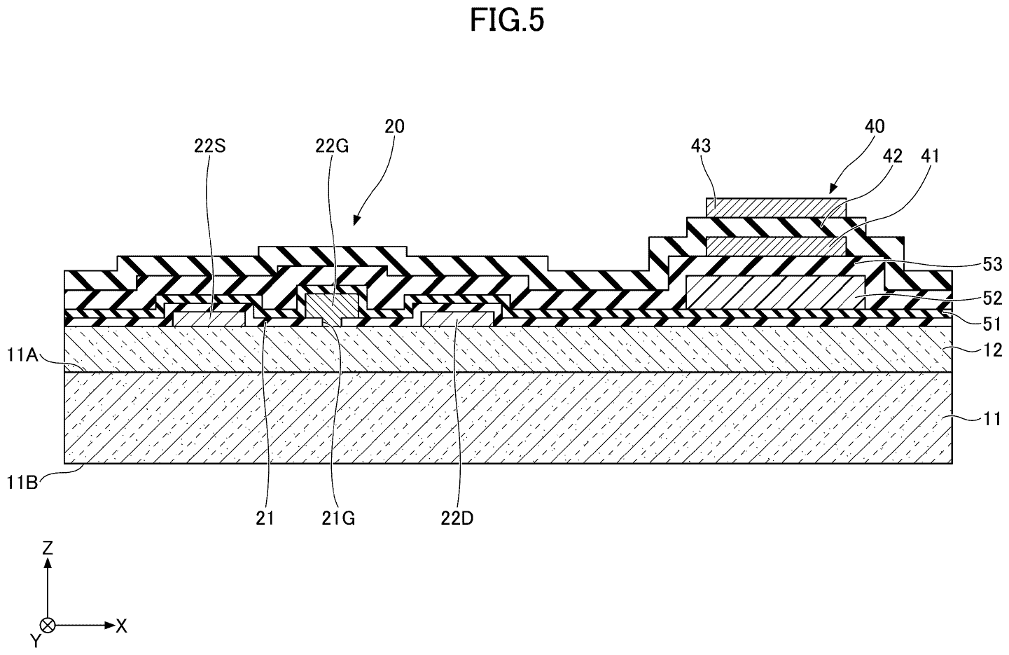

Next, as illustrated in FIG. 5, the lower electrode 41 is formed over the organic stopper layer 52 and on the inorganic stopper layer 53. In other words, the inorganic stopper layer 53 is formed between the organic stopper layer 52 and the lower electrode 41. For the formation of the lower electrode 41, for example, a metal film is formed over the entire surface, and then etching of the metal film is performed. The etching may be dry etching or may be wet etching. The lower electrode 41 may be formed through vapor deposition and lift-off of a metal film. Next, the insulating film 42 is formed on the lower electrode 41 and the inorganic stopper layer 53. The insulating film 42 can be formed, for example, through plasma CVD or sputtering. The insulating film 42 covers the lower electrode 41 and the inorganic stopper layer 53. Next, the upper electrode 43 is formed over the organic stopper layer 52 and on the insulating film 42. In other words, the insulating film 42 is formed between the lower electrode 41 and the upper electrode 43. For the formation of the upper electrode 43, for example, a metal film is formed over the entire surface, and then etching of the metal film is performed. The etching may be dry etching or may be wet etching. The upper electrode 43 may be formed through vapor deposition and lift-off of a metal film.

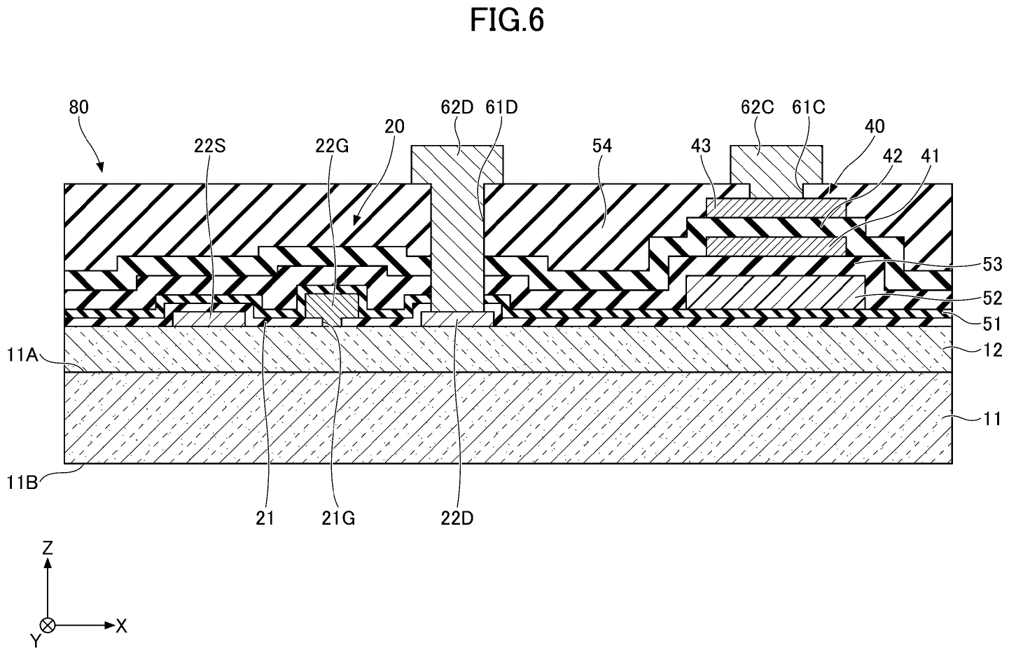

Next, as illustrated in FIG. 6, the interlayer insulating film 54 is formed on the upper electrode 43 and the insulating film 42. The interlayer insulating film 54 can be formed, for example, through plasma CVD or sputtering. The interlayer insulating film 54 covers the upper electrode 43 and the insulating film 42. The upper surface of the interlayer insulating film 54 may be flattened. Next, the openings 61C and 61D are formed. The opening 61C penetrates through the interlayer insulating film 54, and reaches the upper electrode 43.

The opening 61D penetrates through the interlayer insulating film 54, the insulating film 42, the inorganic stopper layer 53, the insulating film 51, and the insulating film 21, and reaches the drain electrode 22D. A different opening may be formed in the same manner as in the opening 61D, and this different opening may reach the source electrode 22S.

Next, the interconnects 62C and 62D are formed on the interlayer insulating film 54. The interconnect 62C contacts the upper electrode 43 through the opening 61C, and the interconnect 62D contacts the drain electrode 22D through the opening 61D. A different opening reaching the source electrode 22S may be formed in the same manner as in the opening 61D, and an interconnect contacting the source electrode 22S through this different opening may be formed on the interlayer insulating film 54 in the same manner as in the interconnect 62D. That is, a different opening may be formed to reach the source electrode 22S in the same manner as in the opening 61D, and an interconnect may be formed on the interlayer insulating film 54 through this different opening in the same manner as in the interconnect 62D.

In the above-described manner, a structure 80 including the FET 20 and the MIM-type capacitor 40 is provided.

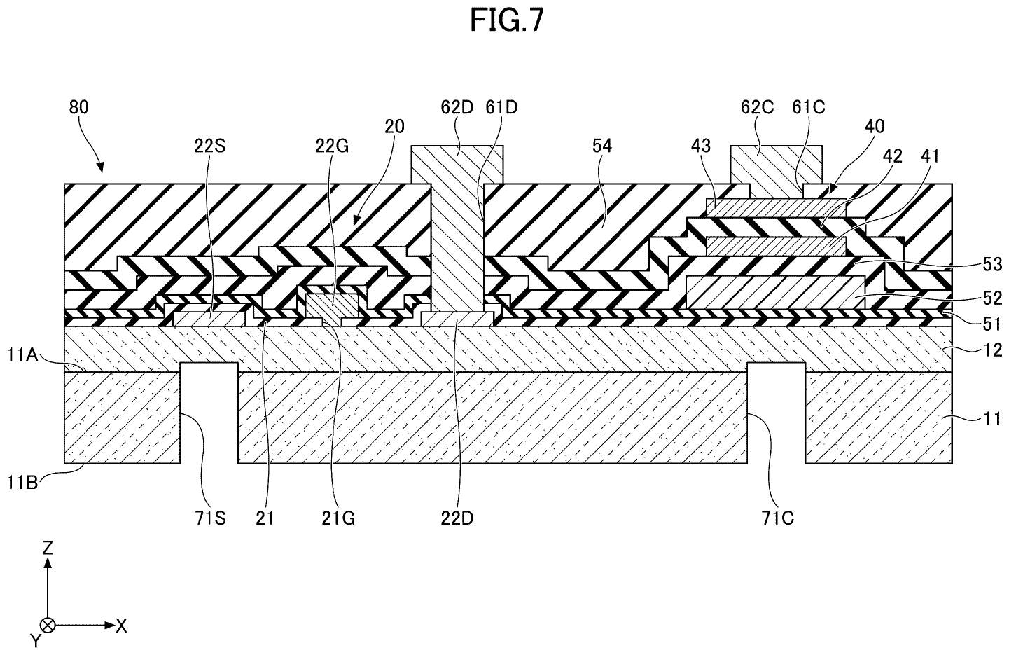

Next, as illustrated in FIG. 7, the through-holes 71C and 71S penetrating through the substrate 11 are formed in the substrate 11 through RIE. The through-hole 71C is formed such that the outline of the through-hole 71C is located inward of the outline of the organic stopper layer 52 in the plan view, and the through-hole 71S is formed such that the outline of the through-hole 71S is located inward of the outline of the source electrode 22S in the plan view. The through-hole 71C overlaps with the lower electrode 41 in the plan view, and reaches the semiconductor layer 12. The through-hole 71S overlaps with the source electrode 22S in the plan view, and reaches the semiconductor layer 12. For the formation of the through-holes 71C and 71S, RIE of the substrate 11 using a resist pattern as a mask is performed. For the etching of the substrate 11, a reactive gas containing fluorine (F), such as carbon tetrafluoride (CF₄), sulfur hexafluoride (SF₆), fluoromethane (CHₓF_{y}), or the like, is used. After this RIE, the semiconductor layer 12 is exposed from the through-holes 71C and 71S. The through-holes 71C and 71S may enter the semiconductor layer 12. The RIE of the substrate 11 is an example of the third reactive ion etching.

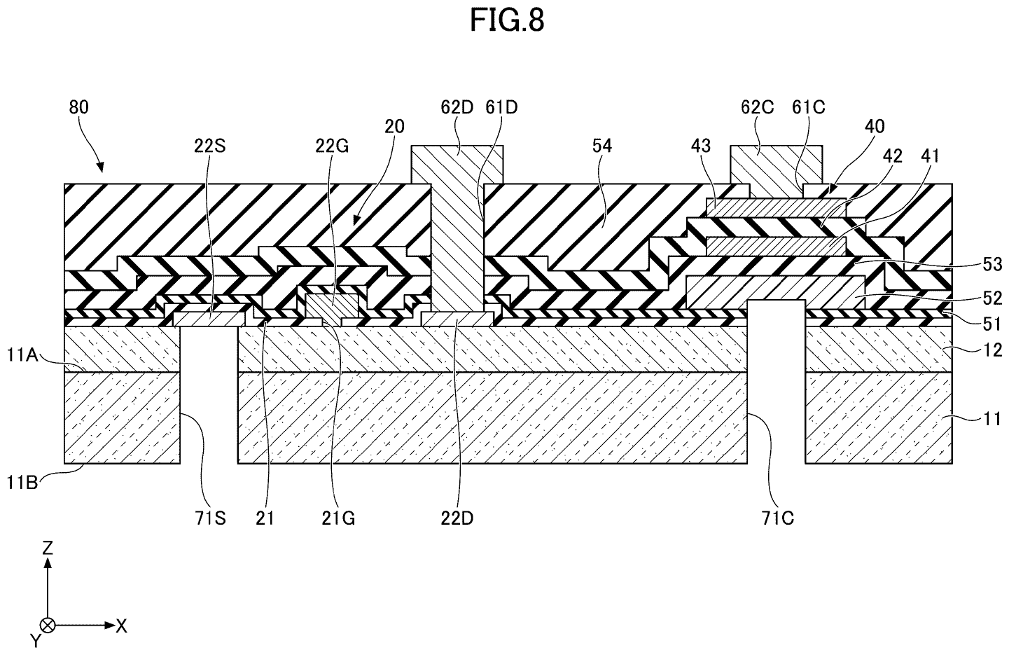

Next, as illustrated in FIG. 8, RIE is performed to extend: the through-hole 71C so as to penetrate through the semiconductor layer 12, the insulating film 21, and the insulating film 51 and reach the organic stopper layer 52; and the through-hole 71S so as to penetrate through the semiconductor layer 12 and reach the source electrode 22S. For etching of the semiconductor layer 12, the insulating film 21, and the insulating film 51, a reactive gas containing chlorine (Cl), such as chlorine (Cl₂), boron trichloride (BCl₃), silicon tetrachloride (SiCl₄), carbon tetrachloride (CCl₄), or the like, is used. This reactive gas does not contain oxygen (O₂). After this RIE, the organic stopper layer 52 is exposed from the through-hole 71C, and the source electrode 22S is exposed from the through-hole 71S. In this RIE, the etching rate of the organic stopper layer 52 is about ⅓ times that of the semiconductor layer 12, the insulating film 21, and the insulating film 51. That is, the organic stopper layer 52 exhibits an etching selectivity of about 3 with respect to the insulating film 21 and the insulating film 51. The through-hole 71C may enter the organic stopper layer 52. In this RIE, the organic stopper layer 52 functions as an etching stopper. Although the source electrode 22S is also exposed to an etching atmosphere, the source electrode 22S is not etched through the RIE using the reactive gas containing chlorine (Cl). The RIE of the semiconductor layer 12, the insulating film 21, and the insulating film 51 is an example of the fourth reactive ion etching. The third reactive ion etching and the fourth reactive ion etching are included in the first reactive ion etching.

When the semiconductor layer 12 is sufficiently thin, the RIE of the substrate 11 and the RIE of the semiconductor layer 12, the insulating film 21, and the insulating film 51 may be performed successively without changing the reactive gas from that used for the etching of the substrate 11.

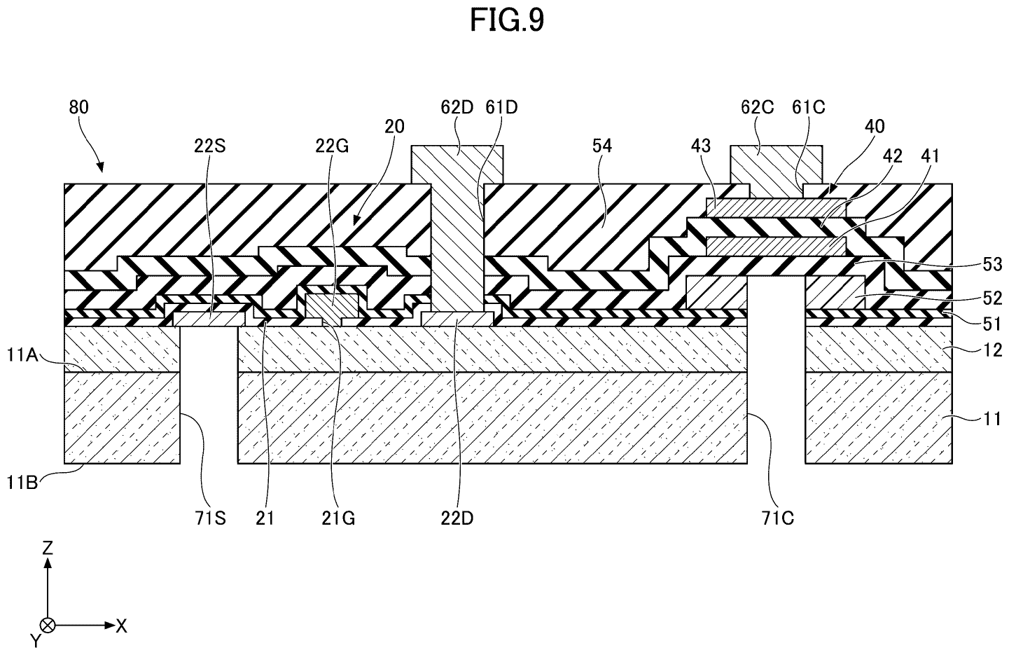

Next, as illustrated in FIG. 9, RIE is performed to extend the through-hole 71C so as to penetrate through the organic stopper layer 52 and reach the inorganic stopper layer 53. For etching of the organic stopper layer 52, a reactive gas containing oxygen (O₂) is used. After this RIE, the inorganic stopper layer 53 is exposed from the through-hole 71C. In this RIE, the etching rate of the inorganic stopper layer 53 is from about 1/100 times through about 1/50 times that of the organic stopper layer 52. That is, the inorganic stopper layer 53 exhibits an etching selectivity of from about 50 through about 100 with respect to the organic stopper layer 52. The through-hole 71C may enter the inorganic stopper layer 53. In this RIE, the inorganic stopper layer 53 functions as an etching stopper. Although the source electrode 22S is also exposed to an etching atmosphere, the source electrode 22S is not etched through the RIE using the reactive gas containing oxygen (O₂). The RIE of the organic stopper layer 52 is an example of the fifth reactive ion etching.

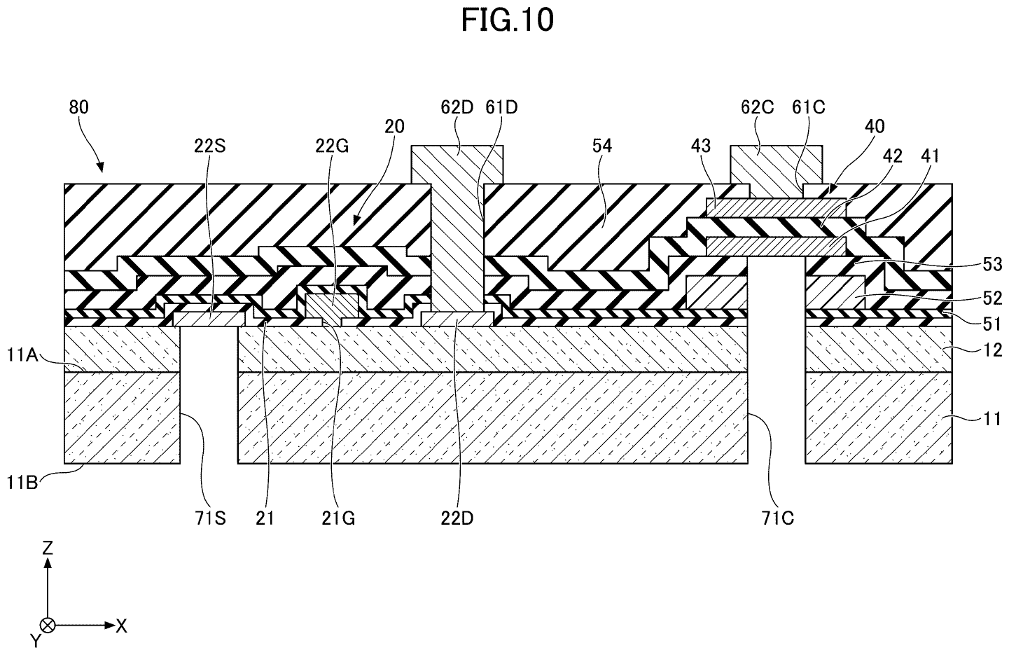

Next, as illustrated in FIG. 10, RIE is performed to extend the through-hole 71C so as to penetrate through the inorganic stopper layer 53 and reach the lower electrode 41. For etching of the inorganic stopper layer 53, a reactive gas containing fluorine (F), such as carbon tetrafluoride (CF₄), sulfur hexafluoride (SF₆), fluoromethane (CHₓF_{y}), or the like, or a reactive gas containing chlorine (Cl), such as chlorine (Cl₂), boron trichloride (BCl₃), silicon tetrachloride (SiCl₄), carbon tetrachloride (CCl₄), or the like, is used. A reactive gas containing both fluorine (F) and chlorine (Cl) may be used for etching of the inorganic stopper layer 53. This reactive gas does not contain oxygen (O₂). In the RIE of the inorganic stopper layer 53, the voltage for generating a plasma and the voltage for inducing a plasma are set to be lower than that for the RIE of the semiconductor layer 12, the insulating film 21, and the insulating film 51. After this RIE, the lower electrode 41 is exposed from the through-hole 71C. The through-hole 71C may enter the lower electrode 41. Although the source electrode 22S is also exposed to an etching atmosphere, the source electrode 22S is not etched through the RIE using the reactive gas containing fluorine (F), the reactive gas containing chlorine (Cl), or the reactive gas containing both fluorine (F) and chlorine (Cl). The RIE of the inorganic stopper layer 53 is an example of the sixth reactive ion etching. The fifth reactive ion etching and the sixth reactive ion etching are included in the second reactive ion etching.

Next, the back electrode 72 is formed (see FIG. 1). The back electrode 72 is formed on the second main surface 11B of the substrate 11, the inner wall surface of the through-hole 71C, the lower surface of the lower electrode 41, the inner wall surface of the through-hole 71S, and the lower surface of the source electrode 22S.

In this manner, the semiconductor device 100 according to the embodiment can be produced.

According to the semiconductor device 100 according to the embodiment, the organic stopper layer 52 is provided between the substrate 11 and the lower electrode 41, and the organic stopper layer 52 functions as an etching stopper when the through-hole 71C is formed in the substrate 11 and the semiconductor layer 12. Therefore, even if RIE is performed at a high power for forming the through-hole 71C in the substrate 11 and the semiconductor layer 12, damage to the lower electrode 41 and the insulating film 42 can be suppressed. Therefore, by forming the through-hole 71C so as to overlap with the lower electrode 41 in the plan view while suppressing a reduction in the breakdown voltage of the MIM-type capacitor 40, the size of the semiconductor device can be reduced.

Because the MIM-type capacitor 40 and the FET 20 are provided at the substrate 11, an MMIC can be formed. Moreover, a part of the through-hole 71C can be formed at the same time as the through-hole 71S.

When the organic stopper layer 52 contains polyimide or benzocyclobutene, the organic stopper layer 52 is readily formed to have a desired thickness. That is, the organic stopper layer 52 can be readily formed to be thick, and can be readily patterned. Further, internal stress does not appreciably remain in the organic stopper layer 52. Thus, the organic stopper layer 52 is not appreciably peeled off, and stress is not appreciably applied from the organic stopper layer 52 to the FET 20. When the thickness of the organic stopper layer 52 is 1 pm or more and 10 um or less, the organic stopper layer 52 is readily allowed to function as an etching stopper while reducing the time required for etching of the organic stopper layer 52. The organic stopper layer 52 having a thickness of 1 μm or more and 10 μm or less can be penetrated through by etching for a short time. The thickness of the organic stopper layer 52 may be 1 μm or more and 5 μm or less, and may be 1 μm or more and 3 μm or less, in accordance with conditions of RIE at the time of forming the through-hole 71C. The organic stopper layer 52 can be readily etched by using a reactive gas containing oxygen.

The inorganic stopper layer 53 can provide favorable adhesiveness between the organic stopper layer 52 and the lower electrode 41. Also, by provision of the inorganic stopper layer 53, damage to the lower electrode 41 during the RIE of the organic stopper layer 52 is readily suppressed. When the thickness of the inorganic stopper layer 53 is 20 nm or more and 500 nm or less, the inorganic stopper layer 53 is readily allowed to function as an etching stopper while reducing the time required for etching of the inorganic stopper layer 53. The inorganic stopper layer 53 having a thickness of 20 nm or more and 500 nm or less can be penetrated through for a short time even through etching that is performed at a power low enough to suppress damage to the lower electrode 41. Also, stress cannot be appreciably applied from the inorganic stopper layer 53 to the FET 20. The thickness of the inorganic stopper layer 53 may be 30 nm or more and 400 nm or less, and may be 50 nm or more and 350 nm or less.

The reactive gas used for the RIE of the semiconductor layer 12, the insulating film 21, and the insulating film 51 and the reactive gas used for the RIE of the inorganic stopper layer 53 do not contain oxygen (O₂). Thus, etching of the organic stopper layer 52 in these RIE processes can be suppressed.

The FET 20 may be of a metal insulator semiconductor (MIS) type, instead of a Schottky type. The present disclosure is applicable to a semiconductor device not including the FET 20. That is, the semiconductor layer 12, the insulating film 21, and the like forming the FET 20 may be absent. Also, the insulating film 51 and the inorganic stopper layer 53 are not essential, and even when the insulating film 51, the inorganic stopper layer 53, or both are not provided, the size of the semiconductor device can be reduced while suppressing a reduction in the breakdown voltage of the capacitor.

Although the embodiments have been described above in detail, the present disclosure is not limited to the specific embodiments, and various modifications and changes are possible within the scope recited in the claims.

What is claimed is:

1. A semiconductor device, comprising:
a substrate including a first main surface and a second main surface that is opposite to the first main surface;
an organic stopper layer that is provided over the first main surface;
a first electrode that is provided over the organic stopper layer;
an insulating film that is provided on the first electrode;
a second electrode that is provided on the insulating film;
a first through-hole that penetrates through the substrate and the organic stopper layer and reaches the first electrode; and
a metal layer that covers the second main surface and a first inner wall surface of the first through-hole and is electrically connected to the first electrode.

2. The semiconductor device according to claim 1, further comprising:
a semiconductor layer that is provided on the first main surface;
a third electrode that is provided on the semiconductor layer; and
a second through-hole that penetrates through the substrate and the semiconductor layer and reaches the third electrode, wherein
the organic stopper layer is provided over the semiconductor layer,
the first through-hole penetrates through the semiconductor layer, and
the metal layer covers a second inner wall surface of the second through-hole and is electrically connected to the third electrode.

3. The semiconductor device according to claim 1, wherein
the organic stopper layer includes polyimide or benzocyclobutene.

4. The semiconductor device according to claim 1, wherein
a thickness of the organic stopper layer is 1 μm or more and 10 μm or less.

5. The semiconductor device according to claim 1, further comprising:
an inorganic stopper layer that is provided between the organic stopper layer and the first electrode, wherein
the first through-hole penetrates through the inorganic stopper layer.

6. The semiconductor device according to claim 5, wherein
a thickness of the inorganic stopper layer is 20 nm or more and 500 nm or less.

7. A production method for a semiconductor device, the production method comprising:
providing a structure that includes a substrate including a first main surface and a second main surface that is opposite to the first main surface, an organic stopper layer that is provided over the first main surface, a first electrode that is provided over the organic stopper layer, an insulating film that is provided on the first electrode, and a second electrode that is provided on the insulating film;
performing first reactive ion etching to form a first through-hole that overlaps with the first electrode in a plan view perpendicular to the first main surface, penetrates the substrate, and reaches the organic stopper layer;
performing second reactive ion etching to extend the first through-hole so as to penetrate through the organic stopper layer and reach the first electrode; and
forming a metal layer that covers the second main surface and a first inner wall surface of the first through-hole and is electrically connected to the first electrode.

8. The production method for the semiconductor device according to claim 7, wherein
the structure further includes
a semiconductor layer provided on the first main surface, and
a third electrode provided on the semiconductor layer,
the organic stopper layer being provided over the semiconductor layer,
performing the first reactive ion etching includes
performing third reactive ion etching to form a portion of the first through-hole, the portion penetrating through the substrate and reaching the semiconductor layer, and to form a second through-hole that overlaps with the third electrode in the plan view, penetrates through the substrate, and reaches the semiconductor layer, and
performing fourth reactive ion etching to extend the first through-hole so as to penetrate through the semiconductor layer and reach the organic stopper layer, and to extend the second through-hole so as to penetrate through the semiconductor layer and reach the third electrode, and
the metal layer covers a second inner wall surface of the second through-hole and is electrically connected to the third electrode.

9. The production method for the semiconductor device according to claim 7, wherein
the structure further includes
an inorganic stopper layer that is provided between the organic stopper layer and the first electrode,
performing the second reactive ion etching includes
performing fifth reactive ion etching to extend the first through-hole so as to penetrate through the organic stopper layer and reach the inorganic stopper layer, and
performing sixth reactive ion etching to extend the first through-hole so as to penetrate through the inorganic stopper layer and reach the first electrode.

10. The production method for the semiconductor device according to claim 9, wherein
a reactive gas containing oxygen is used in the fifth reactive ion etching.
